(19) United States
(12) Patent Application Publication
(10) Pub. No.: US 2006/0255865 A1
(43) Pub. Date: Nov. 16, 2006

(54) Differential switches for voltage controlled oscillator coarse tuning

(75) Inventor: Larry Li, Irvine, CA (US)

Correspondence Address: LAW OFFICES OF CLEMENT CHENG, 17220 NEWHOPE STREET #127, FOUNTAIN VALLEY, CA, 92708, US

(73) Assignee: Comlent Holdings, Inc.

(21) Appl. No.: 11/126,451

(22) Filed: May 11, 2005

(51) Int. Cl. H03B 5/12

(52) U.S. Cl. 331/36 C

(57) ABSTRACT

A voltage controlled oscillator frequency tuner has a first differential switch set and a second differential switch set. Each differential switch set has one pair of switch transistors controlling current to one pair of capacitors. The activating means activates only one set or no sets, and can differential switch switch from the first differential switch set to the second differential switch set. Differential switch switching provides a capacitance difference proportional to the capacitance difference of the first differential switch set capacitor pair and the second differential switch set capacitor pair.

### BACKGROUND OF THE INVENTION

Radio communication devises, from portable telephones to wireless computers, require a stable operating frequency provided by a local oscillator. The Voltage Controlled Oscillator (VCO) is a key element in successful wireless communications, particularly in the receiver end where noise can have a major effect upon the quality even functionality of the wireless devices.

Radio Frequency (RF) circuitries have recently been implemented using CMOS technology instead of bipolar technology the RF circuitries had been using before. A basic VCO design uses two pairs of Field Effect Transistors (FET), one pair of varactors and one pair of capacitors. The capacitances of the varators are continuously changed by changing the control voltage (Vcont). The capacitance of the capacitors can be switched on and off by control voltage and step controlled by switching voltage (Vsw). The VCO frequency steps are dependant of the values of the capacitors and the values of the parasitic capacitance of the MOSFET transistors.

Referring to FIG. 1, a prior art voltage controlled oscillator 10 (VCO) is shown. The current source 11 is to provide a current used by the oscillator circuit. The bias source 12 (Vbias) is connected to a switch transistor M15 to bias the oscillator circuit. The switching voltage source 13 (Vsw) is to provide step selection of the frequency control level. The control voltage 14 (Vcont) is to provide control signal to change the capacitances of PN-junction varactors Cv11 and Cv12.

The oscillator circuit in FIG. 1 comprises first and second switch transistors M11 and M12, respectively connected in a negative resistance configuration across an LC tank circuit. Said LC tank circuit comprises first and second PN-junction varactors Cv11 and Cv12, and first and second inductors L11 and L12. The N side of the diode is connected to Vcont signal 14, where the capacitance of Cv11 and Cv12 are continuously changed by changing the control voltage 14 (Vcont).

Between oscillator circuit and the LC tank connects frequency control circuit. Said frequency controlled circuit comprises first and second switch transistors M13, M14 along with first and second capacitors C11, C12.

However, fabrication process varies, and it is extremely difficult to maintain the fixed parasitic capacitance of elements and components. Also due to the process variations, the capacitors cannot be made small. Therefore, the coarse control frequency steps are not able to be small enough for the VCO designs.

As taught by U.S. Pat. No. 6,700,450 to Rogers, the varactors or capacitors in the switched pair must be large enough so that parasitic capacitance does not reduce the available frequency tuning range to an unacceptable level. Unfortunately, this does not allow fine tuning.

U.S. Pat. No. 6,680,657 discloses a cross-coupled voltage controlled oscillator provided with a cross-coupled differential bipolar transistor voltage controlled oscillator, including a digital tuning means for selecting one of the frequency bands to be tuned. It provides more than one level of band frequency selections and a pair of diodes for analog tuning.

U.S. Pat. No. 6,064,277 discloses an oscillator circuit having a LC tank to reduce phase noise by maximizing the oscillator amplitude and minimizing the drive to the tank.

U.S. Pat. No. 5,218,325 discloses a low noise oscillator including a voltage controlled oscillator, a varactor, a junction field effect transistor and a buffer amplifier which receives the intermediate sinusoidal voltage signal from a tapped microstrip of the voltage controlled oscillator and produces a highly stable output signal proportional to the DC tuning voltage applied to the input of the low noise oscillator. The buffer amplifier employs a dual gate Gallium Arsenide field effect transistor.

### SUMMARY OF THE INVENTION

Briefly, this invention's object is to reduce the phase noise of a Voltage Controlled Oscillator circuitry caused by processing variations. This invention also has an object of reducing the cost of an oscillator circuitry.

A differential switches circuitry is provided to accomplish this and other objects. The differential switches circuitry adds an inverter, two capacitors and two switch transistors.

The present invention can be used in any VCO designs with digital control bits. The digital control bits can come from the register or internal calibration schemes. This invention can also be used in frequency shit key (FSK) modulation.

### BRIEF DESCRIPTION OF THE DRAWINGS

FIG. 1 is a circuit configuration of a prior art differential VCO design.

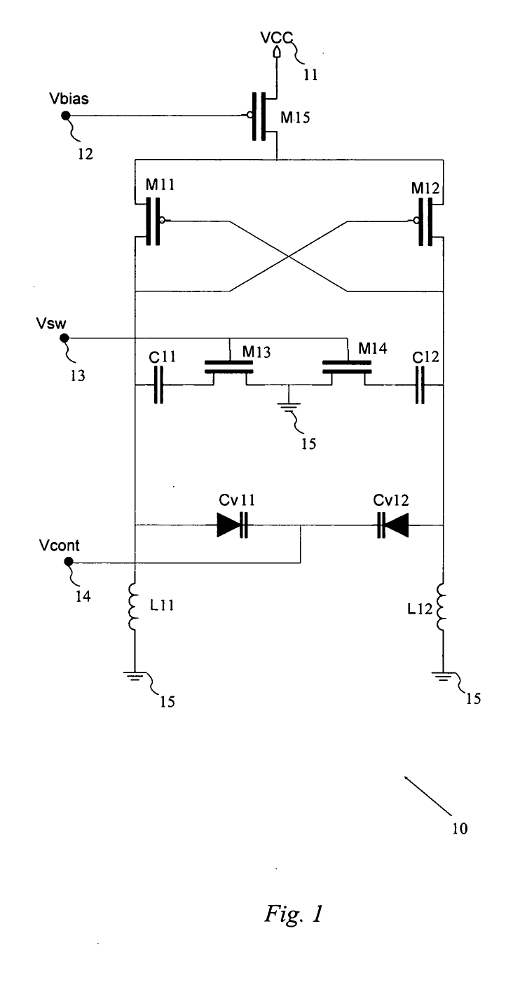

FIG. 2 is a circuit configuration of a differential VCO design, according to the present invention.

### CALL OUT LIST OF THE ELEMENTS

10 Prior Art VCO

11 VCC Input

12 Vbias Input

13 Vsw Input

14 Vcont Input

15 Ground

20 Circuit Configuration of Present Invention

21 VCC Input

22 Vbias Input

23 Vsw Input

24 Vcont Input

25 Ground

26 Inverted Signal

M1-M6 Switch Transistors

C1-C4 Capacitors

Cv1-Cv2 Varactors

L1-L2 Inductors

I1 Inverter

### DETAILED DESCRIPTION OF THE PREFERRED EMBODIMENT

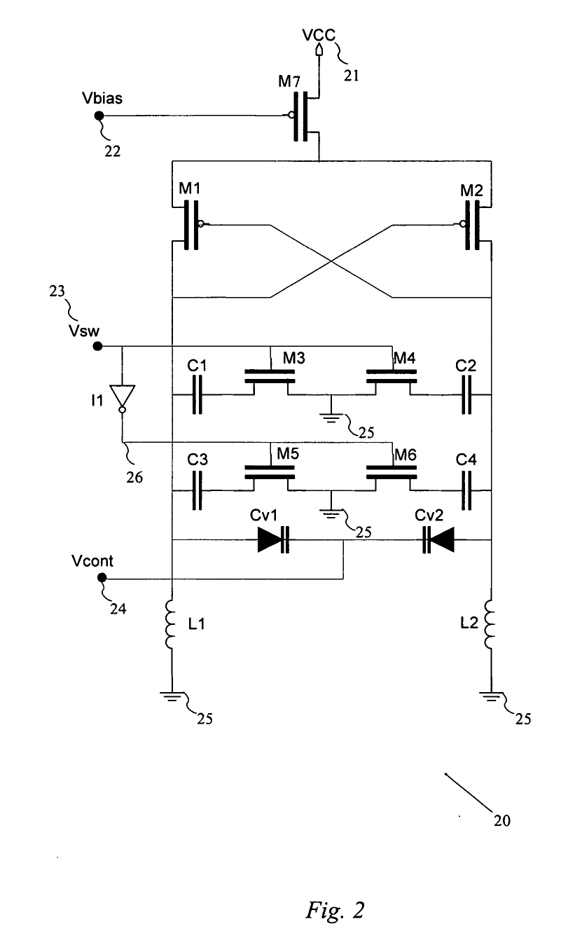

Referring to FIG. 2, a voltage controlled oscillator with differential switch 20 (VCO) is shown. The differential switches circuitry in the present invention introduces a level frequency control circuit comprising an inverter 11, and the first and second frequency control circuit levels. Said second frequency control level comprises first and second switch transistors M5, M6, along with first and second capacitors C3 and C4. The transistor gates M3, M4 and M5, M6 are controlled by an inverted signal produced and controlled by the inverter 11. Only one pair of said transistors is activated at anytime.

The total capacitance differences are the difference of C1, C2 and C3, C4. Since the difference of capacitors can be very small without sacrificing the accuracy of total capacitance, this invention can be designed with very small frequency steps, which are independent of process variation.

The VCO current is set to maximize the voltage swing at the tank to minimize the phase noise. The swing is maximized when the transistors M1 and M2 are made to alternate saturation and cutoff at the top and bottom of the VCO voltage swing. Once the transistors M1 and M2 reach said level, raising current will not cause the swing to grow anymore.

The current source 21 is to provide a current used by the oscillator circuit. The bias source 22 (Vbias) is connected to a switch transistor M7 to form a drain circuit to bias the oscillator circuit. The switching voltage source Vsw 23 is to provide step selection of the frequency control level. The control voltage 24 (Vcont) is to provide control signal to change the capacitances of PN-junction varactors Cv1 and Cv2.

The bias circuit is formed by a common-drain circuit. The drain circuit comprises a bias source 22 (Vbias), a VCC input 21, and a switch transistor M7. The input bias signal, which is generated by an independent bias circuit, passes to the gate of transistor M7, further generating an output bias signal into oscillator circuit. The type of transistor is not limited to as shown in FIG. 2. Any kind of switch transistor can be used in such a bias circuit. Enhancement mode MOSFETs, however, would need a resistor between the gate and the possible supply terminal (or the negative terminal if the MOSFET is P-channel).

The oscillator circuit in FIG. 2 comprises first and second switch transistors M1 and M2, respectively connected in a negative resistance configuration across an LC (Inductance-Capacitance) tank circuit. Said LC tank circuit comprises first and second PN-j unction varactor diodes Cv1 and Cv2, and first and second inductors L1 and L2. The inductors L1 and L2 are made as large as possible to maximize the equivalent parallel resistance while still allowing the varactors to be large enough as the parasitic capacitance does not reduce the frequency tuning to an undesirable level. The N sides of the varactor diodes Cv1 and Cv2 are connected to Vcont signal 14, where the capacitance of Cv1 and Cv2 are continuously changed by changing the control voltage 14 (Vcont). The P sides of the diodes connect, respectively, to the source gates of transistor M1 and M2, linking the upper end to the lower end of the LC tank circuit.

Between the upper and lower LC tank circuit connects frequency control circuit. Said frequency controlled circuit comprises first and second level of frequency controlling circuits. The first level of said frequency control circuit comprises switch transistors M3, M4 along with first and second capacitors C1, C2. The second level of said frequency control circuit comprises switch transistors M5, M6 along with capacitors C3, C4. A switching voltage source 13 (Vsw), providing step selection of the frequency control levels, connects to the gate terminals of transistors M3, M4, M5, and M6. An inverter 11 is connected between the first and second pair of switch transistors. Said inverter 11 receives signal from the switching voltage source 13 (Vsw), then pass an inverted signal to gate terminals of transistors M5 and M6. The source terminals of transistors M3, M4, M5, and M6 are all connected to ground. The drain terminals of said transistors, however, connect with capacitors C1, C2, C3 and C4 respectively before connecting with said LC tank.

1. A voltage controlled oscillator frequency tuner comprising:
a first differential switch set and a second differential switch set; each differential switch set having one pair of switch transistors controlling current to one pair of capacitors;
an activating means activating only one set or no sets, the activating means capable of differential switch switching from the first differential switch set to the second differential switch set;
wherein differential switch switching provides a capacitance difference proportional to the capacitance difference of the first differential switch set capacitor pair and the second differential switch set capacitor pair.

2. The voltage controlled oscillator frequency tuner of claim 1, wherein the activating means is an inverted signal to each differential switch set having one pair of switch transistors, the inverted signal toggling activation between the first and second set.

3. The voltage controlled oscillator frequency tuner of claim 1 further comprising an LC tank means, wherein said LC tank means comprising a pair of switch capacitors, a pair of varactor diodes, and a pair of inductors.

4. The voltage controlled oscillator frequency tuner of claim 3 wherein the LC tank means further comprises a Voltage bias source means and a Voltage controlled means, wherein said Voltage bias means comprises a switch transistor.

5. A voltage controlled oscillator frequency tuner comprising:
a first differential switch set and a second differential switch set; each differential switch set having one pair of switch transistors controlling current to one pair of capacitors;
an inverted signal means activating only one set, the inverted signal means capable of differential switch switching from the first differential switch set to the second differential switch set;
wherein differential switch switching provides a capacitance difference proportional to the capacitance difference of the first differential switch set capacitor pair and the second differential switch set capacitor pair.

6. A voltage controlled oscillator frequency tuner of claim 5 wherein the frequency tuner further comprises a LC tank means, wherein said LC tank means comprising a pair of switch capacitors, a pair of varactor diodes, and a pair of inductors.

7. A voltage controlled oscillator frequency tuner of claim 6 wherein the LC tank means further comprises a Voltage bias source means and a Voltage controlled means, wherein said Voltage bias means comprises a switch transistor.
